(19) United States
(12) Patent Application Publication
(10) Pub. No.: US 2007/0284756 A1
(43) Pub. Date: Dec. 13, 2007

(54) STACKED CHIP PACKAGE

(75) Inventors: Tsung Yueh TSAI, Gangshan Township (TW); Yi Shao LAI, Yonghe City (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING, INC., Kaohsiung (TW)

(21) Appl. No.: 11/624,085

(22) Filed: Jan. 17, 2007

(30) Foreign Application Priority Data
Jun. 12, 2006 (TW) 095120784

(51) Int. Cl. H01L 23/52; H01L 23/48

(52) U.S. Cl. 257/777; 257/690

(57) ABSTRACT

A stacked chip package is provided. The metal bumps disposed on the lower chip are encapsulated by a layer of non-conductive adhesive and the area around by the layer of non-conductive adhesive material is filled with another adhesive. Under such a configuration, it can prevent the upper chip from contacting the bonding wires connected to the lower chip and eliminate the fracture of the upper chip during the wire bonding process.

### CROSS REFERENCE TO RELATED APPLICATION

This application claims the priority benefit of Taiwan Patent Application Serial Number 095120784 filed Jun. 12, 2006, the full disclosure of which is incorporated herein by reference.

### BACKGROUND OF THE INVENTION

1. Field of the Invention

The invention relates to a semiconductor package, and more particularly, to a stacked chip package.

2. Description of the Related Art

As the demand for miniaturization and higher operating speed continues to increase, multi-chip modules (MCMs) have been used in a variety of electronic devices. MCMs, which contain more than one chip in a module, can help minimize the limitations of the operating speed of systems. In addition, MCMs decrease the interconnection length between IC chips and the signal delays and access time can be reduced accordingly.

The most common MCM is the “side-by-side” MCM. In this version, two or more IC chips are mounted next to each other (or side by side) on the principal mounting surface of a common substrate. Interconnections among the chips and conductive traces on the substrate are commonly made via wire bonding. The side-by-side MCM, however, suffers from a disadvantage that the package efficiency is very low since the area of the common substrate increases with an increase in the number of semiconductor chips mounted thereon.

Therefore, referring to FIG. 1, U.S. Pat. No. 5,323,060 discloses a multichip stacked device that includes a first semiconductor chip 110 attached to a substrate 120 and a second semiconductor chip 130 disposed on the first semiconductor chip 110. The chips 110, 130 are respectively wire bonded to the substrate 120. The U.S. Pat. No. 5,323,060 is characterized by applying an adhesive layer 140 between the two chips 110, 130 to provide clearance between the chips 110, 130 for the loops of the bonding wires 150. The adhesive layer 140 has a thickness greater than the loop height defined by the distance between the active surface of the chip 110 and the vertexes of the outwardly projecting loops of the bonding wires 150 so as to prevent the bonding wires 150 from contacting the chip 130. The normal loop height is commonly about 10 to 15 mils. As thinner packages have been developed, the loop height has been reduced with conventional bonding techniques down to about 6 mils by changing in the loop parameters, profile and wire types. However, this loop height is considered a minimum obtainable loop height as attempts to go lower have caused wire damage and poor wire pull strengths. Therefore, using this conventional bonding technique, the adhesive layer 140 must have a thickness of at least 8 mils to prevent the bonding wires 150 from contacting the chip 130. Typical materials for the adhesive layer 140 include epoxy and tape. However, it is very difficult to form an epoxy layer with a stable bond line thickness above 8 mils. In addition, even using a tape with a thickness of 8 mils, it will increase the production cost and the reliability of resulted package will suffer from the CTE mismatch between thermoplastic tape and silicon chip. Besides, as the edge of the second chip 130 is not supported by the adhesive layer 140, the second chip 130 is apt to be cracked as a result of pressure when the edge of the second chip 130 is wire bonded.

Therefore, referring to FIG. 2, the semiconductor industry develops a stacked chip package 200 characterized by using a dummy chip 160 to provide clearance between the chips for the loop of the underlying bonding wire. The dummy chip 160 is interposed between the chips 110, 130 via two adhesive layers 162, 164. Typically, the adhesive layers 162, 164 are made of thermosetting epoxy materials. In addition, as the edge of the second chip 130 is not supported by the adhesive layer 140, the second chip 130 is similarly apt to be cracked when the edge of the second chip 130 is wire bonded.

Accordingly, there exists a need to provide a stacked chip package to solve the aforesaid problems.

### SUMMARY OF THE INVENTION

It is an object of the present invention to provide a stacked chip package that can prevent the upper chip from contacting with the bonding wires connected to the lower chip and avoid the fracture of the upper chip during the wire bonding.

In one embodiment, the stacked chip package includes a first chip disposed on a substrate and a plurality of first metal bumps disposed on the edge of the upper surface of the first chip. The first chip is electrically connected to the substrate by connecting a plurality of first bonding wires from the first metal bumps to the substrate. The first metal bumps are covered by a first adhesive of appropriate thickness. The area surrounded by the first adhesive is filled with a second adhesive. A second chip is disposed on the first adhesive and second adhesive. The edge of the upper surface of the second chip is provided with a plurality of second metal bumps and the second chip is electrically connected to the substrate by connecting a plurality of second bonding wires from the second metal bumps to the substrate. A sealant is used to encapsulate the first and second chips and the first and second bonding wires.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a cross-sectional view of a conventional stacked chip package.

FIG. 2 is a cross-sectional view of another conventional stacked chip package.

FIG. 3 is a cross-sectional view of a stacked chip package according to an embodiment of the present invention.

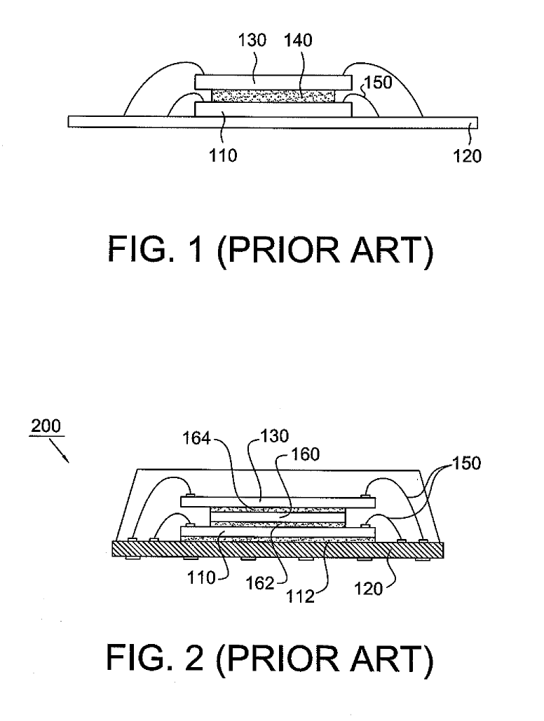

### DETAILED DESCRIPTION OF THE PREFERRED EMBODIMENT

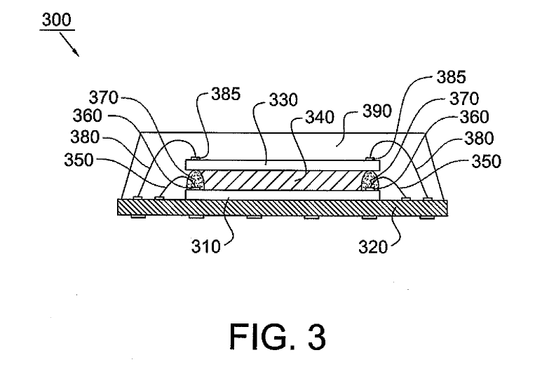

Referring to FIG. 3, a stacked chip package 300 according to an embodiment of the present invention includes a first chip 310 disposed on a substrate 320 and a plurality of metal bumps 360 disposed on the edge of the upper surface of the first chip 310. The first chip 310 is electrically connected to the substrate 320 by connecting a plurality of gold bonding wires 350 from the metal bumps 360 to the substrate 320. The metal bumps 360 are covered by a non-conductive adhesive 370 of appropriate thickness such as dry film or epoxy film. Furthermore, the dry film or the epoxy 370 can be ring-shaped. The area surrounded by the non-conductive adhesive 370 is filled with an adhesive 340 such as a liquid compound or an epoxy. A second chip 330 which is the same size as the first chip 310 is disposed on the non-conductive adhesive 370 and adhesive 340. The non-conductive adhesive 370 acts like a spacer to sustain the distance between the chips 310, 330. The adhesive 370 is also like a combiner and can attach the two chips 310, 330 to each other. In addition, the epoxy 340 can also separate the two chips 310, 330 at a predetermined distance and attach them to each other. The edge of the upper surface of the second chip 330 is provided with a plurality of metal bumps 385 and the second chip 330 is electrically connected to the substrate 320 by connecting a plurality of gold bonding wires 380 from the metal bumps 385 to the substrate 360. A sealant 390 is used to encapsulate the chips 310, 330 and bonding wires 350, 380.

In the stacked chip package 300 of the present invention, the metal bumps 360 disposed on the first chip 310 and the portion length of the bonding wires 350 which are between the first chip 310 and second chip 330 are covered in the non-conductive adhesive 370 so that the occurrence of the bonding wires 350 electrically contacting with the second chip 330 can be avoided. In addition, the second chip 330 is not apt to be cracked during wire bonding since the edge thereof is supported by the adhesive 370.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A stacked chip package, comprising:
a substrate having an upper surface;
a first chip disposed on the upper surface of the substrate;
a plurality of first metal bumps disposed on the edge of the upper surface of the first chip;
a plurality of first bonding wires electrically connecting the first metal bumps to the substrate;
a first adhesive covering the first metal bumps;
a second adhesive filled within the area surrounded by the first adhesive;
a second chip disposed on the first adhesive and second adhesive;
a plurality of second bonding wires electrically connecting the second chip to the substrate; and
a sealant encapsulating the first chip, second chip, first bonding wires and second bonding wires.

2. The stacked chip package as claimed in claim 1, wherein the second adhesive is a liquid compound.

3. The stacked chip package as claimed in claim 1, wherein the second adhesive is an epoxy.

4. The stacked chip package as claimed in claim 1, wherein the first chip and second chip are the same size.

5. The stacked chip package as claimed in claim 1, wherein the portion length of the first bonding wires between the first chip and second chip are covered in the first adhesive.

6. The stacked chip package as claimed in claim 1, wherein the first adhesive has the function of separating the first and second chips apart and attaching the first and second chips to each other.

7. The stacked chip package as claimed in claim 1, wherein the second adhesive has the function of separating the first and second chips apart and attaching the first and second chips to each other.

8. The stacked chip package as claimed in claim 1, wherein the first bonding wires are made of gold.

9. The stacked chip package as claimed in claim 1, wherein the second bonding wires are made of gold.

10. The stacked chip package as claimed in claim 1, wherein the first adhesive and second adhesive are non-conductive.

11. The stacked chip package as claimed in claim 1, wherein the first adhesive is a ring of dry film.

12. The stacked chip package as claimed in claim 1, further comprising:
a plurality of second metal bumps disposed on the edge of the upper surface of the second chip, wherein the second chip is electrically connected to the substrate by connecting the second bonding wires to the second metal bumps.

13. The stacked chip package as claimed in claim 1, wherein the first adhesive and second adhesive are epoxy film.
